(19) United States
(12) Patent Application Publication
(10) Pub. No.: US 2024/0397782 A1
(43) Pub. Date: Nov. 28, 2024

(54) DISPLAY PANEL AND DISPLAY APPARATUS

(71) Applicant: BOE Technology Group Co., Ltd., Beijing (CN)

(72) Inventors: Hao GAO, Beijing (CN); Kuo SHEN, Beijing (CN)

(21) Appl. No.: 18/693,970

(22) PCT Filed: Jul. 5, 2023
(86) PCT No.: PCT/CN2023/105916

§ 371 Date: Mar. 21, 2024

(30) Foreign Application Priority Data
Jul. 29, 2022 (CN) 202210908577.7

(51) Int. Cl. H10K 59/35

(52) U.S. Cl. CPC H10K 59/353

(57) ABSTRACT

A display panel and a display apparatus. The display panel comprises at least one repeat region (10), wherein the repeat region (10) comprises n pixel regions (21, 22, 23, 24), n being a natural number greater than or equal to 3; the pixel region (21, 22, 23, 24) at least comprises a first sub-pixel region (31); the first sub-pixel region (31) has a first central axis (60); and in a repeat region (10), an included angle formed between first central axes (60) of first sub-pixel regions (31) in adjacent pixel regions (21, 22, 23, 24) is 360 degrees/n.

### CROSS-REFERENCE TO RELATED APPLICATION

The present application is a U.S. National Phase Entry of International Application No. PCT/CN2023/105916 having an international filing date of Jul. 5, 2023, which claims priority from Chinese Patent Application No. 202210908577.7, filed to the CNIPA on Jul. 29, 2022. Contents of the above-identified application are incorporated into the present application by reference.

### TECHNICAL FIELD

Embodiments of the present disclosure relate to, but are not limited to, the field of display technologies, and in particular relate to a display panel and a display apparatus.

### BACKGROUND

An Organic Light-Emitting Diode (OLED) is a display lighting technology gradually developed in recent years, especially in the display industry, and it is one of hot spots in the research field of flat panel displays today. Compared with a Liquid Crystal Display (LCD), OLED has advantages such as high response, high contrast, low operation voltage, lightness and thinness, flexibility, low energy consumption, low production cost, self-luminescence, wide viewing angle and high response speed.

### SUMMARY

The following is a summary of subject matters described herein in detail. This summary is not intended to limit the protection scope of the claims.

In a first aspect, an embodiment of the present disclosure provides a display panel including at least one repeated region. The repeated region includes n pixel regions, and n is a natural number greater than or equal to 3. The pixel regions at least include a first sub-pixel region having a first central axis, and in one repeated region, an included angle formed between first central axes of first sub-pixel regions in adjacent pixel regions is 360 degrees/n.

In an exemplary embodiment, the pixel regions further include a second sub-pixel region having a second central axis, and in one repeated region, an included angle formed between second central axes of second sub-pixel regions in adjacent pixel regions is 360 degrees/n.

In an exemplary embodiment, the pixel regions further include a third sub-pixel region having a third central axis, and in one repeated region, an included angle formed between third central axes of third sub-pixel regions in adjacent pixel regions is 360 degrees/n.

In an exemplary embodiment, the repeated region includes four pixel regions arranged in a rectangular manner, and in one repeated region, an included angle between the first central axes of the first sub-pixel regions in adjacent pixel regions is 90 degrees.

In an exemplary embodiment, the first sub-pixel region is in a strip shape.

In an exemplary embodiment, the pixel regions further include a second sub-pixel region and a third sub-pixel region, and the second sub-pixel region and the third sub-pixel region respectively are located at opposite sides of the first central axis of the first sub-pixel region.

In an exemplary embodiment, in adjacent pixel regions, the second sub-pixel region and the third sub-pixel region in adjacent pixel regions are adjacent; and/or, second sub-pixel regions in adjacent pixel regions are adjacent; and/or, third sub-pixel regions in adjacent pixel regions are adjacent.

In an exemplary embodiment, the shapes of the second sub-pixel region and the third sub-pixel region each include at least one of a triangle, a circle, a diamond, a rectangle, and an ellipse.

In an exemplary embodiment, the pixel regions further include a second sub-pixel region and a third sub-pixel region, the first sub-pixel region, the second sub-pixel region and the third sub-pixel region are all in a strip shape, the first sub-pixel region, the second sub-pixel region and the third sub-pixel region are arranged in a row, the second sub-pixel region has a second central axis, the third sub-pixel region has a third central axis, and the first central axis, the second central axis and the third central axis all have the same extension direction.

In an exemplary embodiment, an outer contour of each of the pixel regions includes at least one of a triangle, a circle, a diamond, a rectangle, an ellipse, and a polygon.

In an exemplary embodiment, an outer contour of each of the pixel regions is rectangular, and a ratio of a long side of the outer contour of each of the pixel regions to a short side of the outer contour of each of the pixel regions is less than 3/2 and greater than 1.

In a first aspect, an embodiment of the present disclosure provides a display panel including at least one repeated region. The repeated region includes n pixel regions, and n is 2. The pixel regions at least include a first sub-pixel region having a first central axis, and in one repeated region, an included angle formed between first central axes of first sub-pixel regions in adjacent pixel regions is 90 degrees.

In an exemplary embodiment, the first sub-pixel region is rectangular.

In an exemplary embodiment, the pixel regions further include a second sub-pixel region and a third sub-pixel region, the first sub-pixel region having a first edge portion and a second edge portion that intersect with each other, the second sub-pixel region is adjacent to the first edge portion of the first sub-pixel region, and the third sub-pixel region is adjacent to the second edge portion of the first sub-pixel region.

In an exemplary embodiment, the second sub-pixel region or the third sub-pixel region is disposed between the first sub-pixel regions in adjacent pixel regions.

In a third aspect, an embodiment of the present disclosure further provides a display apparatus, including any one of the display panels described above.

Other aspects may become clear after the drawings and the detailed description are read and understood.

### BRIEF DESCRIPTION OF DRAWINGS

The drawings are used for providing an understanding of technical solutions of the present application and form a part of the specification. They are used for explaining the technical solutions of the present application together with embodiments of the present application, and do not constitute a limitation on the technical solutions of the present application.

FIG. 1 is a schematic diagram of a structure of a display panel according to an embodiment of the present application.

FIG. 2 is a schematic diagram of a cross-sectional structure of a display panel according to an embodiment of the present application.

FIG. 3a is a first schematic diagram of a structure of a repeated region in a display panel according to an embodiment of the present application.

FIG. 3b is a second schematic diagram of a structure of a repeated region in a display panel according to an embodiment of the present application.

FIG. 3c is a third schematic diagram of a structure of a repeated region in a display panel according to an embodiment of the present application.

FIG. 3d is a schematic diagram of a structure of four repeated regions in a display panel according to an embodiment of the present application.

FIG. 4 is a fourth schematic diagram of a structure of a repeated region in a display panel according to an embodiment of the present application.

FIG. 5a is a fifth schematic diagram of a structure of a repeated region in a display panel according to an embodiment of the present application.

FIG. 5b is a sixth schematic diagram of a structure of a repeated region in a display panel according to an embodiment of the present application.

FIG. 6 is a graph of light emitted from a display panel in a chromaticity diagram in related art.

FIG. 7 is a graph showing the brightness of light emitted from the display panel in related art.

### DETAILED DESCRIPTION

To make the objectives, technical solutions, and advantages of the present disclosure clearer, embodiments of the present disclosure will be described in detail below with reference to the drawings. It is to be noted that implementations may be implemented in various forms. Those of ordinary skills in the art can easily understand such a fact that implementations and contents may be transformed into various forms without departing from the purpose and scope of the present disclosure. Therefore, the present disclosure should not be explained as being only limited to the contents recorded in the following implementations. The embodiments and features in the embodiments of the present disclosure may be randomly combined with each other if there is no conflict.

In the drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the drawings schematically illustrate ideal examples, and an implementation of the present disclosure is not limited to shapes, numerical values, or the like shown in the drawings.

Ordinal numerals “first”, “second”, “third” and the like in the specification are set to avoid confusion between composition elements, but are not intended to limit in numbers.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the composition elements with reference to the drawings, which are only for the convenience of describing the present specification and simplifying the description, and do not indicate or imply that the involved devices or elements are required to have specific orientations, are structured and operated in the specific orientations, and thus should not be understood as limitations on the present disclosure. The positional relationships between the composition elements may be changed as appropriate according to a direction in which each composition element is described. Therefore, appropriate replacements based on situations are allowed, and the positional relationships are not limited to the expressions described in the specification.

In the specification, unless otherwise expressly specified and defined, terms “mounting”, “connection”, and “join” should be understood in a broad sense. For example, it may be a fixed connection, or a detachable connection, or an integral connection; it may be a mechanical connection or an electrical connection; it may be a direct connection, or an indirect connection through an intermediate, or an internal communication between two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Alternatively, the first electrode may be a source electrode, and the second electrode may be a drain electrode. In cases that transistors with opposite polarities are used, or a current direction changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of composition elements through an element with a certain electrical action. “An element with a certain electrical action” is not particularly limited as long as electric signals may be sent and received between the connected composition elements. Examples of the “element with a certain electrical action” not only include an electrode and a wiring, but also include a switch element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” means that a boundary is not defined so strictly and numerical values within a range of process and measurement errors are allowed.

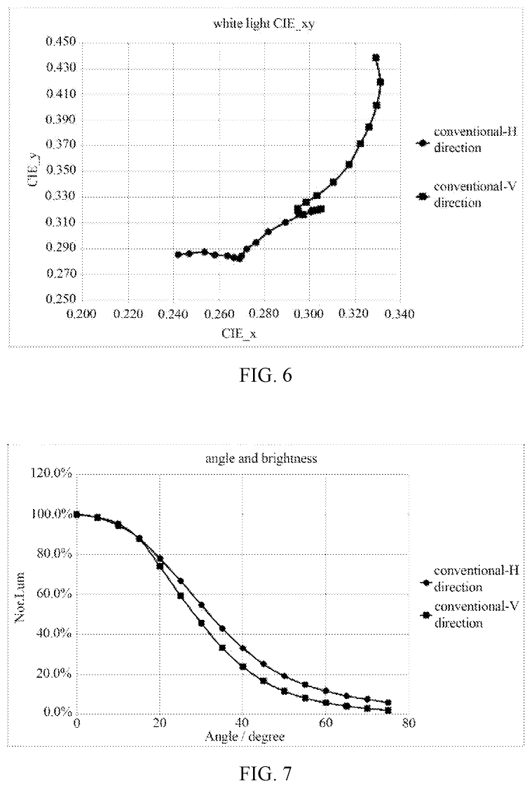

FIG. 6 is a graph of light emitted from a display panel in a chromaticity diagram in related art; and FIG. 7 is a graph showing the brightness of light emitted from the display panel in related art. According to the research of the inventor, it is found that in the display panel of the related art, the presence of a black matrix or a reflective structure in the color film structure layer affects the large-angle light emission of the display panel. In a direction parallel to the display panel, when the lengths of the pixel regions in a horizontal direction (H direction) and a vertical direction (V direction) are different, the brightness of the large-angle light emission will be changed, thus causing the brightness and color deviation asymmetry problems in the horizontal direction (H direction) and the vertical direction (V direction), as shown in FIGS. 6 and 7. FIG. 6 illustrates the curve change graph of the light emitted from the display panel in the 1931cie chromaticity diagram of the related art; and FIG. 7 illustrates the curve change graph of the brightness of light emitted from the display panel of the related art.

An embodiment of the present application provides a display panel including at least one repeated region. The repeated region includes n pixel regions, and n is a natural number greater than or equal to 3. The pixel regions at least include a first sub-pixel region having a first central axis. In one repeated region, an included angle formed between first central axes of first sub-pixel regions in adjacent pixel regions is 360 degrees/n. For example, n may be 3, the repeated region includes 3 pixel regions, and an included angle formed between first central axes of first sub-pixel regions in adjacent pixel regions is 120 degrees. Alternatively, n may be 4, the repeated region includes 4 pixel regions, and an included angle formed between first central axes of first sub-pixel regions in adjacent pixel regions is 90 degrees. In some embodiments, n may also be 5, 6, 7, 8, etc. Embodiments of the present application will not be repeated here.

The display panel of the embodiment of the present application improves the color deviation and brightness inconsistency of the display panel and improves the display effect of the display panel by making the included angle formed between the first central axes of the first sub-pixel regions in adjacent pixel regions to be 360 degrees/n.

In some exemplary embodiments, the pixel regions further includes a second sub-pixel region having a second central axis. In one repeated region, an included angle formed between second central axes of second sub-pixel regions in adjacent pixel regions is 360 degrees/n.

In some exemplary embodiments, the pixel regions further includes a third sub-pixel region having a third central axis. In one repeated region, an included angle formed between third central axes of third sub-pixel regions in adjacent pixel regions is 360 degrees/n.

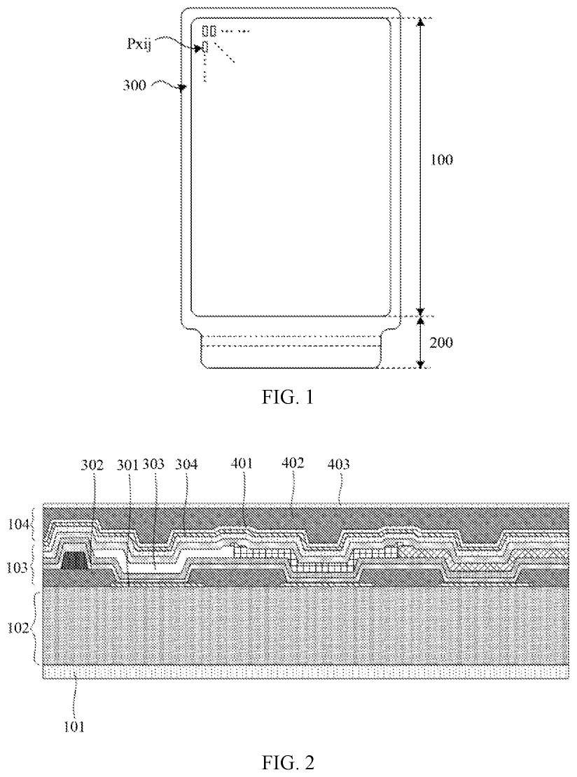

FIG. 1 is a third schematic diagram of a structure of a display panel according to an embodiment of the present application. As shown in FIG. 1, the display panel may include a display region 100, a bonding region 200 located on one side of the display region 100, and a bezel region 300 located on the other sides of the display region 100. In some examples, the display region 100 may be a flat region, the display region 100 may include a plurality of repeated regions, and the repeated regions may include a plurality of pixel regions. The pixel regions may include a plurality of sub-pixel regions Pxij, the plurality of sub-pixel regions Pxij may be configured to display a dynamic picture or a stationary image, and the display region 100 may be referred to as an active area (AA). In some examples, the display panel may be a flexible substrate, and accordingly the display panel may be deformable, for example, may be crimped, bent, folded, or curled.

In some exemplary embodiments, the bonding region 200 may include a fan-out region, a bending region 202, a drive chip region, and a bonding pin region that are arranged sequentially along a direction away from the display region 100. The fan-out region is connected to the display region 100 and at least includes data fan-out lines. Multiple data fan-out lines are configured to be connected with the data signal lines of the display region 100 in a fan-out routing manner. The bending region is connected to the fan-out region and may include a composite insulation layer provided with a groove, and is configured to enable the drive chip region and the bonding pin region to be bent to a back of the display region 100. An integrated circuit (IC) may be disposed in the drive chip region, and the integrated circuit may be configured to be connected with the plurality of data fan-out lines. The bonding pin region may include a bonding pad, and the bonding pad may be configured to be bonded and connected with an external flexible printed circuit (FPC).

In some exemplary embodiments, at least one pixel region may include a first sub-pixel region emitting a first color light, a second sub-pixel region emitting a second color light, and a third sub-pixel region emitting a third color light. Each sub-pixel region may include a pixel circuit and a light emitting element. The pixel circuit is electrically connected to a scan signal line, a data signal line, and a light emitting control line respectively. The pixel circuit may be configured to receive a data voltage transmitted by the data signal line under control of the scan signal line and the light emitting control line, and output a corresponding current to the light emitting element. The light emitting element in each sub-pixel region is connected to a pixel circuit of a sub-pixel region where the light emitting element is located, and is configured to emit light with a corresponding brightness in response to a current output by the pixel circuit of the sub-pixel region where the light emitting element is located.

In some exemplary embodiments, the first sub-pixel region may be a blue sub-pixel region (B) emitting blue light, the second sub-pixel region may be a red sub-pixel region (R) emitting red light, and the third sub-pixel region may be a green sub-pixel region (G) emitting green light. The light emitting elements of the three sub-pixel regions form an RGB pixel arrangement.

FIG. 2 is a schematic diagram of a cross-sectional structure of a display panel according to an embodiment of the present application. FIG. 2 illustrates a structure of three sub-pixel regions in the display region 100. As shown in FIG. 2, in a direction perpendicular to the display panel, the display panel may include a base substrate 101, and a drive circuit layer 102, a light emitting structure layer 103, an encapsulation layer 104 and a color film structure layer which are sequentially disposed on the base substrate 101. In some possible implementations, the display panel may include another film layer, such as a touch structure layer, which is not limited in the present disclosure.

In some exemplary embodiments, the base substrate 101 may be a flexible base or may be a rigid base. The drive circuit layer 102 of each sub-pixel region may include a pixel circuit composed of multiple transistors and capacitors. The light emitting structure layer 103 of each sub-pixel region may at least include an anode 301, a pixel definition layer 302, an organic light emitting layer 303 and a cathode 304. The anode 301 is connected to the pixel circuit, the organic light emitting layer 303 is connected to the anode 301, the cathode 304 is connected to the organic light emitting layer 303, and the organic light emitting layer 303 emits light of a corresponding color under driving of the anode 301 and the cathode 304. The encapsulation structure layer 104 may include a first encapsulation layer 401, a second encapsulation layer 402, and a third encapsulation layer 403 that are stacked. The first encapsulation layer 401 and the third encapsulation layer 403 may be made of an inorganic material, and the second encapsulation layer 402 may be made of an organic material. The second encapsulation layer 402 is disposed between the first encapsulation layer 401 and the third encapsulation layer 403 to form a stacked structure of inorganic material/organic material/inorganic material, which may ensure that external moisture cannot enter the light emitting structure layer 103.

In some exemplary embodiments, the organic light emitting layer 303 may include an emitting layer (EML), and any one or more of following layers: a hole injection layer (HIL), a hole transport layer (HTL), an electron block layer (EBL), a hole block layer (HBL), an electron transport layer (ETL), and an electron injection layer (EIL). In some examples, one or more layers of hole injection layers, hole transport layers, electron block layers, hole block layers, electron transport layers, and electron injection layers of all sub-pixels may be respectively connected together to be a common layer. Emitting layers of adjacent sub-pixels may be overlapped slightly, or may be mutually isolated.

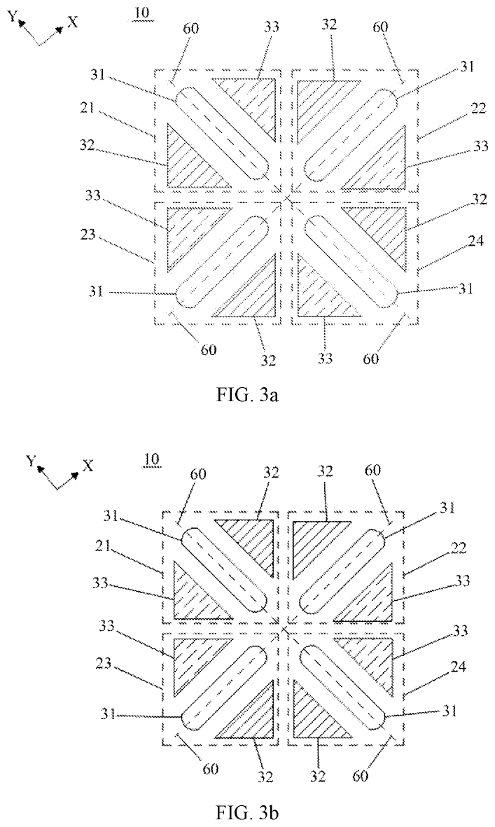

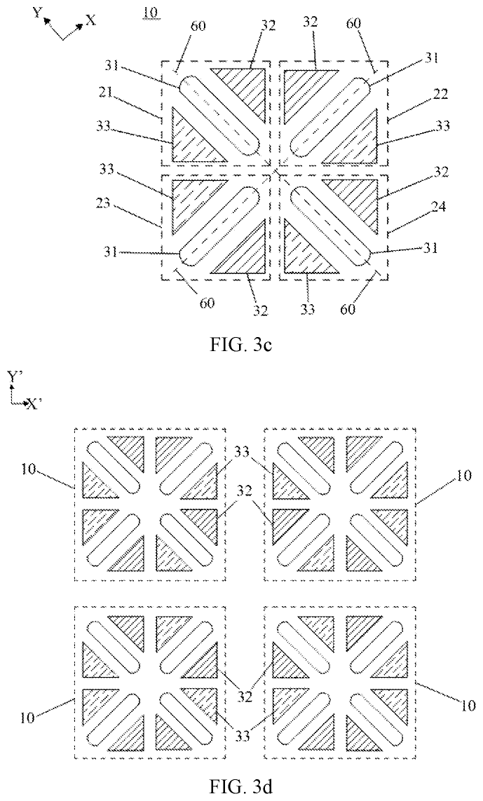

FIG. 3a is a first schematic diagram of a structure of a repeated region in a display panel according to an embodiment of the present application. In some exemplary embodiments, as shown in FIG. 3a, an outer contour of one repeated region 10 is rectangular. One repeated region 10 includes a first pixel region 21, a second pixel region 22, a third pixel region 23, and a fourth pixel region 24. Outer contours of the first pixel region 21, the second pixel region 22, the third pixel region 23, and the fourth pixel region 24 are all rectangular. The first pixel region 21, the second pixel region 22, the third pixel region 23, and the fourth pixel region 24 are arranged in a rectangular manner. The first pixel region 21 and the second pixel region 22 are arranged in a row, the third pixel region 23 and the fourth pixel region 24 are arranged in a row, the first pixel region 21 and the third pixel region 23 are arranged in a column, and the second pixel region 22 and the fourth pixel region 24 are arranged in a column.

In some exemplary embodiments, as shown in FIG. 3a, in one repeated region 10, the outer contour of each pixel region may be rectangular, and a ratio of a long side to a short side of the outer contour of each pixel region is less than 3/2 and greater than 1.

In some exemplary embodiments, as shown in FIG. 3a, the first pixel region 21, the second pixel region 22, the third pixel region 23, and the fourth pixel region 24 each include a first sub-pixel region 31, a second sub-pixel region 32, and a third sub-pixel region 33. The first sub-pixel region 31 is in a strip shape. The first sub-pixel region 31 in each pixel region has a first central axis 60.

In some exemplary embodiments, as shown in FIG. 3a, in one repeated region 10, the included angle between the first central axes 60 of the first sub-pixel regions 31 in adjacent pixel regions is 90 degrees.

The display panel of the embodiment of the present application improves the color deviation and brightness inconsistency of the display panel and improves the display effect of the display panel by making the included angle formed between the first central axes of the first sub-pixel regions in adjacent pixel regions to be 90 degrees.

In some exemplary embodiments, as shown in FIG. 3a, the second sub-pixel region 32 and the third sub-pixel region 33 have the same shape and area, for example, the second sub-pixel region 32 and the third sub-pixel region 33 are both isosceles right triangles. The second sub-pixel region 32 and the third sub-pixel region 33 are symmetrically disposed on both sides of the first central axis 60 with the first central axis 60 of the first sub-pixel region 31 as an axis.

In some embodiments, the second sub-pixel region and the third sub-pixel region may also be of other shapes. For example, the shapes of the second sub-pixel region and the third sub-pixel region may each include at least one of a circle, a diamond, a rectangle, and an ellipse.

In some exemplary embodiments, as shown in FIG. 3a, in the first pixel region 21, the first central axis 60 of the first sub-pixel region 31 extends along a second direction (e.g. direction Y), and the second sub-pixel region 32 and the third sub-pixel region 33 are respectively located on opposite sides of the first central axis 60 of the first sub-pixel region 31. The second sub-pixel region 32, the first sub-pixel region 31 and the third sub-pixel region 33 are arranged in sequence at intervals along a first direction (e.g. direction X). The first direction is perpendicular to the second direction.

In some exemplary embodiments, as shown in FIG. 3a, in the second pixel region 22, the first central axis 60 of the first sub-pixel region 31 extends along the first direction (e.g. direction X), and the second sub-pixel region 32 and the third sub-pixel region 33 are respectively located on opposite sides of the first central axis 60 of the first sub-pixel region 31. The second sub-pixel region 32, the first sub-pixel region 31 and the third sub-pixel region 33 are arranged in sequence at intervals along the second direction (e.g. direction Y).

In some exemplary embodiments, as shown in FIG. 3a, in the third pixel region 23, the first central axis 60 of the first sub-pixel region 31 extends along the first direction (e.g. direction X), and the second sub-pixel region 32 and the third sub-pixel region 33 are respectively located on opposite sides of the first central axis 60 of the first sub-pixel region 31. The second sub-pixel region 32, the first sub-pixel region 31 and the third sub-pixel region 33 are arranged in sequence at intervals along the second direction (e.g. direction Y).

In some exemplary embodiments, as shown in FIG. 3a, in the fourth pixel region 24, the first central axis 60 of the first sub-pixel region 31 extends along the second direction (e.g. direction Y), and the second sub-pixel region 32 and the third sub-pixel region 33 are respectively located on opposite sides of the first central axis 60 of the first sub-pixel region 31. The second sub-pixel region 32, the first sub-pixel region 31 and the third sub-pixel region 33 are arranged in sequence at intervals along the first direction (e.g. direction X).

In some exemplary embodiments, as shown in FIG. 3a, the included angle between the first central axis 60 of the first sub-pixel region 31 in the first pixel region 21 and the first central axis 60 of the first sub-pixel region 31 in the second pixel region 22, and the included angle between the first central axis 60 of the first sub-pixel region 31 in the first pixel region 21 and the first central axis 60 of the first sub-pixel region 31 in the third pixel region 23 are both 90 degrees. The included angle between the first central axis 60 of the first sub-pixel region 31 in the second pixel region 22 and the first central axis 60 of the first sub-pixel region 31 in the first pixel region 21, and the included angle between the first central axis 60 of the first sub-pixel region 31 in the second pixel region 22 and the first central axis 60 of the first sub-pixel region 31 in the fourth pixel region 24 are both 90 degrees. The included angle between the first central axis 60 of the first sub-pixel region 31 in the fourth pixel region 24 and the first central axis 60 of the first sub-pixel region 31 in the second pixel region 22, and the included angle between the first central axis 60 of the first sub-pixel region 31 in the fourth pixel region 24 and the first central axis 60 of the first sub-pixel region 31 in the third pixel region 23 are both 90 degrees. The included angle between the first central axis 60 of the first sub-pixel region 31 in the third pixel region 23 and the first central axis 60 of the first sub-pixel region 31 in the fourth pixel region 24, and the included angle between the first central axis 60 of the first sub-pixel region 31 in the third pixel region 23 and the first central axis 60 of the first sub-pixel region 31 in the first pixel region 21 are both 90 degrees.

In some exemplary embodiments, as shown in FIG. 3a, in one repeated region 10, the second sub-pixel region and the third sub-pixel region in adjacent pixel regions are adjacent. Specifically, the second sub-pixel region 32 in the first pixel region 21 is adjacent to the third sub-pixel region 33 in the third pixel region 23, and the third sub-pixel region 33 in the first pixel region 21 is adjacent to the second sub-pixel region 32 in the second pixel region 22. The second sub-pixel region 32 in the second pixel region 22 is adjacent to the third sub-pixel region 33 in the first pixel region 21, and the third sub-pixel region 33 in the second pixel region 22 is adjacent to the second sub-pixel region 32 in the fourth pixel region 24. The second sub-pixel region 32 in the fourth pixel region 24 is adjacent to the third sub-pixel region 33 in the second pixel region 22, and the third sub-pixel region 33 in the fourth pixel region 24 is adjacent to the second sub-pixel region 32 in the third pixel region 23. The second sub-pixel region 32 in the third pixel region 23 is adjacent to the third sub-pixel region 33 in the fourth pixel region 24, and the third sub-pixel region 33 in the third pixel region 23 is adjacent to the second sub-pixel region 32 in the first pixel region 21.

FIG. 3b is a second schematic diagram of a structure of one repeated region in a display panel according to an embodiment of the present application. In some exemplary embodiments, as shown in FIG. 3b, in one repeated region 10, the second sub-pixel regions in adjacent pixel regions are adjacent; and the third sub-pixel regions in adjacent pixel regions are adjacent. Specifically, the second sub-pixel region 32 in the first pixel region 21 is adjacent to the second sub-pixel region 32 in the second pixel region 22. The third sub-pixel region 33 in the second pixel region 22 is adjacent to the third sub-pixel region 33 in the fourth pixel region 24. The second sub-pixel region 32 in the fourth pixel region 24 is adjacent to the second sub-pixel region 32 in the third pixel region 23. The third sub-pixel region 33 in the third pixel region 23 is adjacent to the third sub-pixel region 33 in the first pixel region 21.

FIG. 3c is a third schematic diagram of a structure of one repeated region in a display panel according to an embodiment of the present application. In some exemplary embodiments, as shown in FIG. 3c, in one repeated region 10, the second sub-pixel region and the third sub-pixel region in adjacent pixel regions are adjacent; the second sub-pixel regions in adjacent pixel regions are adjacent; and the third sub-pixel regions in adjacent pixel regions are adjacent. Specifically, the second sub-pixel region 32 in the first pixel region 21 is adjacent to the second sub-pixel region 32 in the second pixel region 22; the third sub-pixel region 33 in the second pixel region 22 is adjacent to the second sub-pixel region 32 in the fourth pixel region 24; the third sub-pixel region 33 in the fourth pixel region 24 is adjacent to the second sub-pixel region 32 in the third pixel region 23; the third sub-pixel region 33 in the third pixel region 23 is adjacent to the third sub-pixel region 33 in the first pixel region 21.

FIG. 3d is a schematic diagram of a structure of four repeated regions in a display panel according to an embodiment of the present application. In some exemplary embodiments, the display panel of the embodiment of the present application may include a plurality of repeated regions, and adjacent repeated regions may be symmetrically arranged such that sub-pixel regions of the same color in adjacent repeated regions are adjacent. For example, the plurality of repeated regions may be arranged in a row along a third direction (e.g. direction X′), and the plurality of repeated regions may be arranged in a column along a fourth direction (e.g. direction Y′). In the third direction (e.g. direction X′), the second sub-pixel regions in adjacent repeated regions are adjacent, and the third sub-pixel regions in adjacent repeated regions are adjacent. In a fourth direction (e.g. direction Y′), the second sub-pixel regions in adjacent repeated regions are adjacent, and the third sub-pixel regions in adjacent repeated regions are adjacent, as shown in FIG. 3d. The third direction (e.g. direction X′) is perpendicular to the fourth direction (e.g. direction Y′).

In some exemplary embodiments, the first sub-pixel region 31 may be a blue sub-pixel region (B) that emits blue light, the second sub-pixel region 32 may be a red sub-pixel region (R) that emits red light, and the third sub-pixel region 33 may be a green sub-pixel region (G) that emits green light.

In some embodiments, the outer contour of the repeated region may also be of other shapes. For example, the outer contour of the repeated region may be at least one of a triangle, a circle, a diamond, an ellipse, and a polygon. Polygons can include pentagons, hexagons, etc.

In some embodiments, the outer contour of the pixel region may also be of other shapes. For example, the outer contour of the pixel region may be at least one of a triangle, a circle, a diamond, an ellipse, and a polygon. Polygons can include pentagons, hexagons, etc.

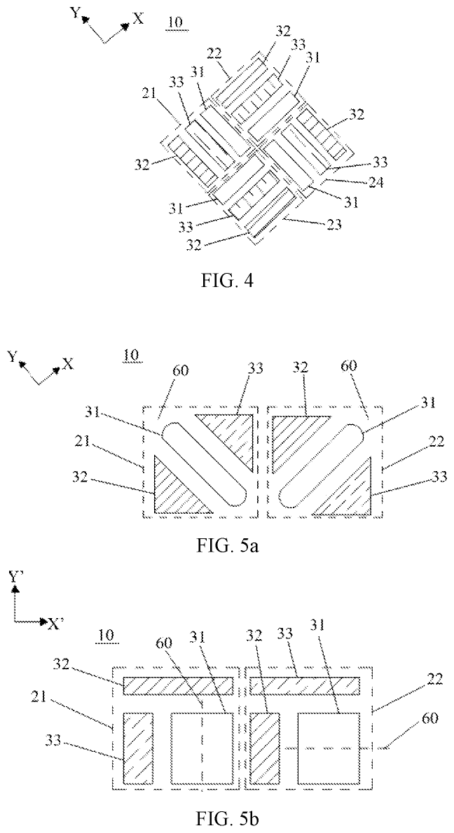

FIG. 4 is a fourth schematic diagram of a structure of a repeated region in a display panel according to an embodiment of the present application. In some exemplary embodiments, as shown in FIG. 4, the outer contour of one repeated region 10 is in shape of diamond. One repeated region 10 includes a first pixel region 21, a second pixel region 22, a third pixel region 23, and a fourth pixel region 24. The outer contours of the first pixel region 21, the second pixel region 22, the third pixel region 23, and the fourth pixel region 24 are all in a shape of diamond. The first pixel region 21, the second pixel region 22, the third pixel region 23, and the fourth pixel region 24 are arranged in a diamond manner. The first pixel region 21 and the second pixel region 22 are arranged in a first direction, the third pixel region 23 and the fourth pixel region 24 are arranged in the first direction, the first pixel region 21 and the third pixel region 23 are arranged in a second direction, and the second pixel region 22 and the fourth pixel region 24 are arranged in the second direction.

In some exemplary embodiments, as shown in FIG. 4, the first pixel region 21, the second pixel region 22, the third pixel region 23, and the fourth pixel region 24 each include a first sub-pixel region 31, a second sub-pixel region 32, and a third sub-pixel region 33. The first sub-pixel region 31, the second sub-pixel region 32, and the third sub-pixel region 33 are all in a strip shape. The first sub-pixel region 31 has a first central axis, the second sub-pixel region 32 has a second central axis, and the third sub-pixel region 33 has a third central axis. In one pixel region, extension directions of the first central axis, the second central axis and the third central axis are all the same.

In some exemplary embodiments, as shown in FIG. 4, in the first pixel region 21, the first central axis, the second central axis and the third central axis all extend in the second direction (e.g. direction Y). The second sub-pixel region 32, the third sub-pixel region 33, and the first sub-pixel region 31 are arranged in sequence at intervals along the first direction (for example, direction X).

In some exemplary embodiments, as shown in FIG. 4, in the second pixel region 22, the first central axis, the second central axis, and the third central axis all extend along the first direction (e.g., direction X). The second sub-pixel region 32, the third sub-pixel region 33, and the first sub-pixel region 31 arranged in sequence at intervals along the second direction (e.g. direction Y).

In some exemplary embodiments, as shown in FIG. 4, in the fourth pixel region 24, the first central axis, the second central axis, and the third central axis all extend along the second direction (e.g. direction Y). The second sub-pixel region 32, the third sub-pixel region 33, and the first sub-pixel region 31 are arranged in sequence at intervals along the first direction (e.g. direction X).

In some exemplary embodiments, as shown in FIG. 4, in the third pixel region 23, the first central axis, the second central axis and the third central axis all extend along the first direction (e.g. direction X). The second sub-pixel region 32, the third sub-pixel region 33, and the first sub-pixel region 31 are arranged in sequence at intervals along the second direction (e.g. direction Y).

In some exemplary embodiments, as shown in FIG. 4, in one repeated region 10, the included angle between the first central axes of the first sub-pixel regions 31 in adjacent pixel regions is 90 degrees. The included angle between the second central axes of the second sub-pixel regions 32 in adjacent pixel regions is 90 degrees. The included angle between the third central axes of the third sub-pixel regions 33 in adjacent pixel regions is 90 degrees.

The display panel of the embodiment of the present application improves the color deviation and brightness inconsistency of the display panel and improves the display effect of the display panel by making the included angle formed between the first central axes of the first sub-pixel regions in adjacent pixel regions to be 90 degrees.

The display panel of the embodiment of the present application improves the color deviation and brightness inconsistency of the display panel and improves the display effect of the display panel by making the included angle formed between the second central axes of the second sub-pixel region in adjacent pixel region to be 90 degrees.

The display panel of the embodiment of the present application improves the color deviation and brightness inconsistency of the display panel and improves the display effect of the display panel by making the included angle formed between the third central axes of the third sub-pixel region in adjacent pixel region to be 90 degrees.

An embodiment of the present application also provides a display panel including at least one repeated region. The repeated region includes n pixel regions, and n is equal to 2. The pixel region at least includes a first sub-pixel region having a first central axis, and in one repeated region, an included angle formed between the first central axes of the first sub-pixel regions in adjacent pixel regions is 90 degrees.

The display panel of the embodiment of the present application improves the color deviation and brightness inconsistency of the display panel and improves the display effect of the display panel by making the included angle formed between the first central axes of the first sub-pixel regions in adjacent pixel regions to be 90 degrees.

FIG. 5a is a fifth schematic diagram of a structure of a repeated region in a display panel according to an embodiment of the present application. In some exemplary embodiments, as shown in FIG. 5a, an outer contour of one repeated region 10 is rectangular. One repeated region 10 includes a first pixel region 21 and a second pixel region 22. The outer contours of the first pixel region 21 and the second pixel region 22 are both rectangular. The first pixel region 21 and the second pixel region 22 are arranged in a row.

In some exemplary embodiments, as shown in FIG. 5a, the first pixel region 21 and the second pixel region 22 each include a first sub-pixel region 31, a second sub-pixel region 32 and a third sub-pixel region 33. The first sub-pixel region 31 is in a strip shape. The first sub-pixel region 31 in each pixel region has a first central axis 60. The structure of the first pixel region 21 and the second pixel region 22 in the display panel of the embodiment of the present application is the same as the structure of the first pixel region 21 and the second pixel region 22 in the display panel shown in FIG. 3a, and the description of this embodiment of the present application will not be repeated here.

In some exemplary embodiments, as shown in FIG. 5a, in one repeated region 10, the included angle between the first central axis 60 of the first sub-pixel region 31 in the first pixel region 21 and the first central axis 60 of the first sub-pixel region 31 in the second pixel region 22 is 90 degrees.

FIG. 5b is a sixth schematic diagram of a structure of a repeated region in a display panel according to an embodiment of the present application. In some exemplary embodiments, as shown in FIG. 5b, an outer contour of one repeated region 10 is rectangular. One repeated region 10 includes a first pixel region 21 and a second pixel region 22. The outer contours of the first pixel region 21 and the second pixel region 22 are both rectangular. The first pixel region 21 and the second pixel region 22 are arranged along a third direction (X′).

In some exemplary embodiments, as shown in FIG. 5b, the first pixel region 21 and the second pixel region 22 each include a first sub-pixel region 31, a second sub-pixel region 32 and a third sub-pixel region 33. The first sub-pixel region 31 is rectangular, for example, the first sub-pixel region 31 is square. The first sub-pixel region 31 in each pixel region has a first central axis 60.

In some exemplary embodiments, as shown in FIG. 5b, in the first pixel region 21, the first central axis 60 of the first sub-pixel region 31 extends along a fourth direction (e.g. direction Y′). The first sub-pixel region 31 has a first edge portion and a second edge portion, and the first edge portion and the second edge portion are two adjacent edge portions of the first sub-pixel region 31. The first edge portion extends along the third direction (e.g. direction X′), and the second edge portion extends along the fourth direction (e.g. direction Y′). The second sub-pixel region 32 extends along the third direction (e.g. direction X′) and is adjacent to the first edge portion of the first sub-pixel region 31. The third sub-pixel region 33 extends along the fourth direction (e.g. direction Y′) and is adjacent to the second edge portion of the first sub-pixel region 31. The third direction is perpendicular to the fourth direction.

In some exemplary embodiments, as shown in FIG. 5b, in the first pixel region 21, the second sub-pixel region 32 has two edges extending along the fourth direction (e.g. direction Y′), and the two edges are respectively located on opposite sides of the second sub-pixel region 32 in the third direction (e.g. direction X′). One edge of the second sub-pixel region 32 is flush with an edge of the third sub-pixel region 33 away from the first sub-pixel region 31 in the fourth direction (e.g. direction Y′), and the other edge of the second sub-pixel region 32 is flush with an edge of the first sub-pixel region 31 away from the third sub-pixel region 33 in the fourth direction (e.g. direction Y′).

In some exemplary embodiments, as shown in FIG. 5b, in the second pixel region 22, the first central axis 60 of the first sub-pixel region 31 extends in the third direction (e.g. direction X′). The first sub-pixel region 31 has a first edge portion and a second edge portion, and the first edge portion and the second edge portion are two adjacent edge portions of the first sub-pixel region 31. The first edge portion extends along the third direction (e.g. direction X′), and the second edge portion extends along the fourth direction (e.g. direction Y′). The third sub-pixel region 33 extends along the third direction (e.g. direction X′) and is adjacent to the first edge portion of the first sub-pixel region 31. The second sub-pixel region 32 extends along the fourth direction (e.g. direction Y′) and is adjacent to the second edge portion of the first sub-pixel region 31.

In some exemplary embodiments, as shown in FIG. 5b, in the second pixel region 22, the third sub-pixel region 33 has two edges extending along the fourth direction (e.g. direction Y′), and the two edges are respectively located on opposite sides of the third sub-pixel region 33 in the third direction (e.g. direction X′). One edge of the third sub-pixel region 33 is flush with an edge of the second sub-pixel region 32 away from the first sub-pixel region 31 in the fourth direction (e.g. direction Y′), and the other edge of the third sub-pixel region 33 is flush with an edge of the first sub-pixel region 31 away from the second sub-pixel region 32 in the fourth direction (e.g. direction Y′).

In some exemplary embodiments, as shown in FIG. 5b, in one repeated region 10, the included angle between the first central axis 60 of the first sub-pixel region 31 in the first pixel region 21 and the first central axis 60 of the first sub-pixel region 31 in the second pixel region 22 is 90 degrees.

In some exemplary embodiments, in one repeated region 10, a second sub-pixel region 32 or a third sub-pixel region 33 is provided between first sub-pixel regions 31 in adjacent pixel regions. For example, a second sub-pixel region 32 in the second pixel region 22 is provided between the first sub-pixel region 31 in the first pixel region 21 and the first sub-pixel region 31 in the second pixel region 22, as shown in FIG. 5b.

An embodiment of the present disclosure provides a mask, the mask includes a mask body and at least two openings provided in the mask body, and the at least two openings are used for forming the sub-pixel regions in the same color in the display panel of the embodiment of the present disclosure. For example, each opening in the mask is used to form the first sub-pixel region in the display panel of the embodiment of the present disclosure.

In some exemplary embodiments, a minimum distance between adjacent opening edges is greater than or equal to 20 microns to avoid problems such as difficult etching, insufficient use strength, and the like due to too close opening edges.

An embodiment of the present disclosure further provides a display apparatus, including any one of the display panels described above. The display apparatus includes a mobile phone, a tablet computer, a wearable smart product (such as a smart watch, a bracelet, or the like), a personal digital assistant (PDA), a vehicle-mounted computer, or the like. A specific form of the above display apparatus is not specially limited in the embodiments of the present application.

Although implementations disclosed in the present disclosure are described above, the described contents are only implementations which are used for facilitating the understanding of the present disclosure, but are not intended to limit the present application. Any skilled person in the art to which the present disclosure pertains may make any modification and variation in a form and details of implementation without departing from the spirit and scope of the present disclosure. However, the patent protection scope of the present application should be subject to the scope defined in the appended claims.

1. A display panel comprising at least one repeated region, wherein the repeated region comprises n pixel regions, n is a natural number greater than or equal to 3, the pixel regions at least comprise a first sub-pixel region having a first central axis, and in one repeated region, an included angle formed between first central axes of first sub-pixel regions in adjacent pixel regions is 360 degrees/n.

2. The display panel according to claim 1, wherein the pixel regions further comprise a second sub-pixel region having a second central axis, and in one repeated region, an included angle formed between second central axes of second sub-pixel regions in adjacent pixel regions is 360 degrees/n.

3. The display panel according to claim 1, wherein the pixel regions further comprise a third sub-pixel region having a third central axis, and in one repeated region, an included angle formed between third central axes of third sub-pixel regions in adjacent pixel regions is 360 degrees/n.

4. The display panel according to claim 1, wherein the repeated region comprises four pixel regions arranged in a rectangular manner, and in one repeated region, an included angle between the first central axes of the first sub-pixel regions in adjacent pixel regions is 90 degrees.

5. The display panel according to claim 1, wherein the first sub-pixel region is in a strip shape.

6. The display panel according to claim 5, wherein the pixel regions further comprise a second sub-pixel region and a third sub-pixel region, and the second sub-pixel region and the third sub-pixel region are respectively located on opposite sides of the first central axis of the first sub-pixel region.

7. The display panel according to claim 6, wherein the second sub-pixel region and the third sub-pixel region in adjacent pixel regions are adjacent; and/or, second sub-pixel regions in adjacent pixel regions are adjacent; and/or, third sub-pixel regions in adjacent pixel regions are adjacent.

8. The display panel according to claim 6, wherein the shapes of the second sub-pixel region and the third sub-pixel region each comprise at least one of a triangle, a circle, a diamond, a rectangle, and an ellipse.

9. The display panel according to claim 1, wherein the pixel regions further comprise a second sub-pixel region and a third sub-pixel region, the first sub-pixel region, the second sub-pixel region and the third sub-pixel region are all in a strip shape, the first sub-pixel region, the second sub-pixel region and the third sub-pixel region are arranged in an row, the second sub-pixel region has a second central axis, the third sub-pixel region has a third central axis, and the first central axis, the second central axis and the third central axis all have the same extension direction.

10. The display panel according to claim 1, wherein an outer contour of each of the pixel regions comprises at least one of a triangle, a circle, a diamond, a rectangle, an ellipse, and a polygon.

11. The display panel according to claim 1, wherein an outer contour of each of the pixel regions is rectangular, and a ratio of a long side of the outer contour of each of the pixel regions to a short side of the outer contour of each of the pixel regions is less than 3/2 and greater than 1.

12. A display panel, comprising at least one repeated region, wherein the repeated region comprises n pixel regions, n is 2, the pixel regions at least comprise a first sub-pixel region having a first central axis, and in one repeated region, an included angle formed between first central axes of first sub-pixel regions in adjacent pixel regions is 90 degrees.

13. The display panel according to claim 12, wherein the first sub-pixel region is rectangular.

14. The display panel according to claim 13, wherein the pixel regions further comprise a second sub-pixel region and a third sub-pixel region, the first sub-pixel region having a first edge portion and a second edge portion that intersect with each other, the second sub-pixel region is adjacent to the first edge portion of the first sub-pixel region, and the third sub-pixel region is adjacent to the second edge portion of the first sub-pixel region.

15. The display panel according to claim 14, wherein the second sub-pixel region or the third sub-pixel region is provided between the first sub-pixel regions in adjacent pixel regions.

16. A display apparatus, comprising the display panel according to claim 1.

17. The display panel according to claim 2, wherein an outer contour of each of the pixel regions comprises at least one of a triangle, a circle, a diamond, a rectangle, an ellipse, and a polygon.

18. The display panel according to claim 3, wherein an outer contour of each of the pixel regions comprises at least one of a triangle, a circle, a diamond, a rectangle, an ellipse, and a polygon.

19. The display panel according to claim 2, wherein an outer contour of each of the pixel regions is rectangular, and a ratio of a long side of the outer contour of each of the pixel regions to a short side of the outer contour of each of the pixel regions is less than 3/2 and greater than 1.

20. The display panel according to claim 3, wherein an outer contour of each of the pixel regions is rectangular, and a ratio of a long side of the outer contour of each of the pixel regions to a short side of the outer contour of each of the pixel regions is less than 3/2 and greater than 1.
